(19) United States
(12) Patent Application Publication
(10) Pub. No.: US 2026/0011485 A1
(43) Pub. Date: Jan. 8, 2026

(54) COUPLING INDUCTOR AND POWER CONVERSION MODULE WITH SAME

(71) Applicant: Delta Electronics, Inc., Taoyuan City (TW)

(72) Inventors: Zhongwang Yang, Shanghai (CN); Bo Li, Shanghai (CN); Kun Mei, Shanghai (CN); Chaowei Fu, Shanghai (CN)

(21) Appl. No.: 19/257,968

(22) Filed: Jul. 2, 2025

(30) Foreign Application Priority Data
Jul. 4, 2024 (CN) 202410895238.9

(51) Int. Cl. H01F 27/29; H01F 27/24; H02M 3/00; H05K 1/18; H05K 7/14

(52) U.S. Cl. CPC H01F 27/29; H01F 27/24; H02M 3/003; H05K 1/181; H05K 7/1427

(57) ABSTRACT

A coupling inductor and a power conversion module with the coupling inductor are provided. The coupling inductor includes a magnetic core and a winding assembly. The winding assembly includes a first power winding and a second power winding. A shared flux path is provided between the first power winding and the second power winding. Two opposite terminals of the first power winding are exposed on the bottom surface of the magnetic core. A portion of the first power winding is exposed on the top surface of the magnetic core and configured as a first heat dissipation part. Two opposite terminals of the second power winding are exposed on the bottom surface of the magnetic core. A portion of the second power winding is exposed on the top surface of the magnetic core and configured as a second heat dissipation part.

### CROSS-REFERENCE TO RELATED APPLICATION

This application claims priority to China Patent Application No. 202410895238.9, filed on Jul. 4, 2024. The entire contents of the above-mentioned patent application are incorporated herein by reference for all purposes.

### FIELD OF THE INVENTION

The present disclosure relates to an inductor, and more particularly to a coupling inductor and a power conversion module with the coupling inductor.

### BACKGROUND OF THE INVENTION

With the rapid development of Artificial Intelligence (AI), servers, data centers and high-performance computing infrastructures have become critical components in modern technological ecosystems. The demand for these infrastructures has surged due to their pivotal role in enabling advanced computational tasks and large-scale data processing. As a result, power systems serving as the core energy source for these infrastructures have gained unprecedented importance. As computing power and data throughput increase, high power density, energy efficiency and advanced thermal management and heat dissipation technologies have emerged as key directions in power system development. Moreover, the continuous upgrades of core chips such as CPUs (Central Processing Units) and GPUs (Graphics Processing Units) for high-performance computing in these infrastructures have led to stricter requirements for the thermal performance and the power density of power systems to meet the needs of today's AI infrastructures.

In modern data centers, Point of Load (POL) power supplies used for low-voltage and high-current applications are usually based on the circuitry topologies of voltage regulators. The circuitry topology of the conventional voltage regulator usually includes an inductor and switching elements (e.g., MOSFET switches). However, a thermal resistance between the inductor and the switching elements results in some drawbacks. For example, due to the thermal resistance, the heat generated by the inductor is difficult to be effectively transferred to the cooling system, which limits the improvement of power density.

Therefore, it is important to provide a coupling inductor and a power conversion module with the coupling inductor in order to overcome the drawbacks of the conventional technologies.

### SUMMARY OF THE INVENTION

The present disclosure provides a coupling inductor and a power conversion module with the coupling inductor. A terminal of a winding assembly of the coupling inductor is electrically connected to a switching device. Furthermore, a portion of the winding assembly is exposed on a top surface of a magnetic core and configured as a heat dissipation part. In other words, the power winding of the winding assembly is in direct contact with the switching device. Since the thermal resistance is greatly reduced, the heat dissipation performance and the power density of the coupling inductor can be effectively enhanced.

In accordance with an aspect of the present disclosure, a coupling inductor is provided. The coupling inductor is electrically connected to a heating element. The coupling inductor includes a magnetic core and a winding assembly. The magnetic core includes a top surface and a bottom surface. The top surface and the bottom surface are opposed to each other. The winding assembly includes a first power winding and a second power winding. A shared flux path is provided between the first power winding and the second power winding. The first power winding and the second power winding are partially disposed within the magnetic core. Two opposite terminals of the first power winding are exposed on the bottom surface of the magnetic core and respectively formed as a first outer connection part and a second outer connection part. A portion of the first power winding is exposed on the top surface of the magnetic core and configured as a first heat dissipation part. Two opposite terminals of the second power winding are exposed on the bottom surface of the magnetic core and respectively formed as a third outer connection part and a fourth outer connection part. A portion of the second power winding is exposed on the top surface of the magnetic core and configured as a second heat dissipation part. The first outer connection part and the third outer connection part are electrically connected to the heating element, and heat generated by the heating element is conducted via the first outer connection part and the third outer connection part to the first heat dissipation part and the second heat dissipation part. The winding assembly outputs power via the second outer connection part and the fourth outer connection part.

In accordance with another aspect of the present disclosure, a power conversion module is provided. The power conversion module includes a circuit board and a coupling inductor. The circuit board has a first surface and a second surface. The first surface and the second surface of the circuit board are opposed to each other. A heating element is disposed on the first surface of the circuit board. The heating element has a first outer surface and a second outer surface. The first outer surface and the second outer surface are opposed to each other. The coupling inductor is electrically connected to the second outer surface of the heating element. The coupling inductor includes a magnetic core and a winding assembly. The magnetic core includes a top surface and a bottom surface. The top surface and the bottom surface are opposed to each other. The winding assembly includes a first power winding and a second power winding. A shared flux path is provided between the first power winding and the second power winding. The first power winding and the second power winding are partially disposed within the magnetic core. Two opposite terminals of the first power winding are exposed on the bottom surface of the magnetic core and respectively formed as a first outer connection part and a second outer connection part. A portion of the first power winding is exposed on the top surface of the magnetic core and configured as a first heat dissipation part. Two opposite terminals of the second power winding are exposed on the bottom surface of the magnetic core and respectively formed as a third outer connection part and a fourth outer connection part. A portion of the second power winding is exposed on the top surface of the magnetic core and configured as a second heat dissipation part. The first outer connection part and the third outer connection part are electrically connected to the heating element, and heat generated by the heating element is conducted via the first outer connection part and the third outer connection part to the first heat dissipation part and the second heat dissipation part. The winding assembly outputs power via the second outer connection part and the fourth outer connection part. The second outer connection part and the fourth outer connection part are soldered on the first surface of the circuit board.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1A is a schematic perspective view illustrating the structure of a coupling inductor according to an embodiment of the present disclosure and taken from a top viewpoint;

FIG. 1B is a schematic exploded view illustrating the structure of the coupling inductor shown in FIG. 1A;

FIG. 1C is a schematic perspective view illustrating the structure of the coupling inductor shown in FIG. 1A and taken from a bottom viewpoint;

FIG. 2 is a schematic circuit diagram illustrating the circuitry topology of a single-module power conversion circuit where the coupling inductor of FIG. 1A is applied;

FIG. 3 schematically illustrates the relationship between the coupling inductor shown in FIG. 1A, a circuit board and a switching device;

FIG. 4 is a schematic perspective view illustrating the structure of a switching device and a circuit board shown in FIG. 2;

FIG. 5A is a schematic perspective view illustrating the structure of a power conversion module including a coupling inductor according to an embodiment of the present disclosure and taken from a top viewpoint;

FIG. 5B is a schematic perspective view illustrating the structure of the coupling inductor shown in FIG. 5A and taken from a bottom viewpoint;

FIG. 5C is a schematic exploded view illustrating the coupling inductor shown in FIG. 5A;

FIG. 5D schematically illustrates a winding assembly of the coupling inductor shown in FIG. 5A;

FIG. 6 is a schematic perspective view illustrating a variant example of the coupling inductor shown in FIG. 5A;

FIG. 7A is a schematic exploded view illustrating the structure of a power conversion module according to an embodiment of the present disclosure; and

FIG. 7B is a schematic exploded view illustrating the power conversion module shown in FIG. 7A and taken from another viewpoint.

### DETAILED DESCRIPTION OF THE EMBODIMENT

The present disclosure will now be described more specifically with reference to the following embodiments. It is noted that the following descriptions of the present disclosure are presented herein for purpose of illustration and description only. It is not intended to be exhaustive or to be limited to the precise from disclosed.

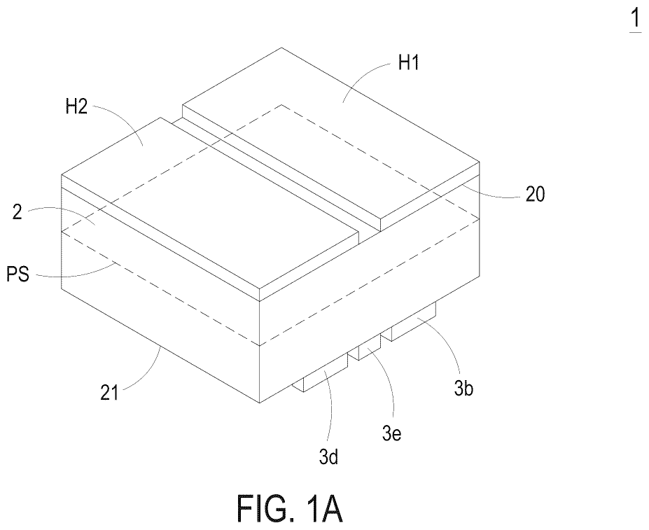

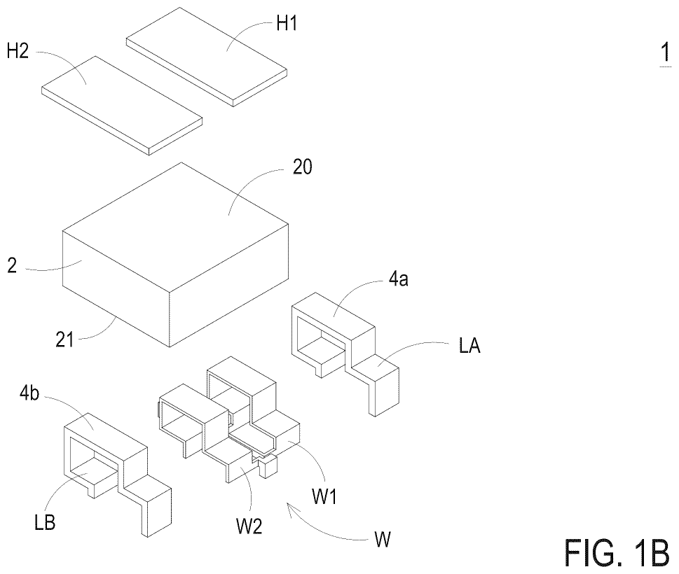

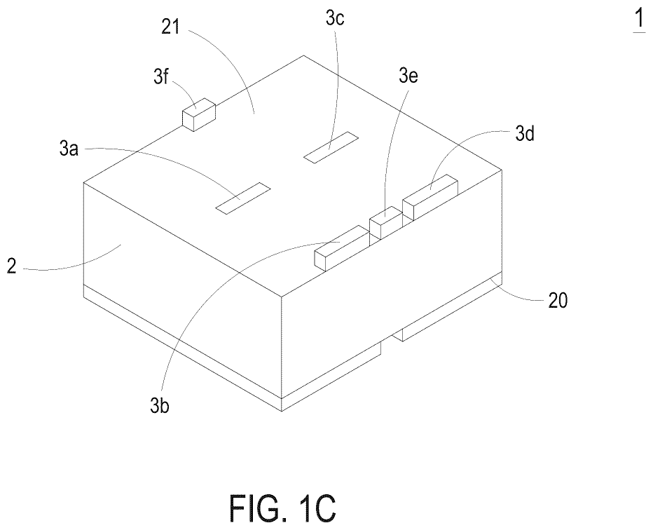

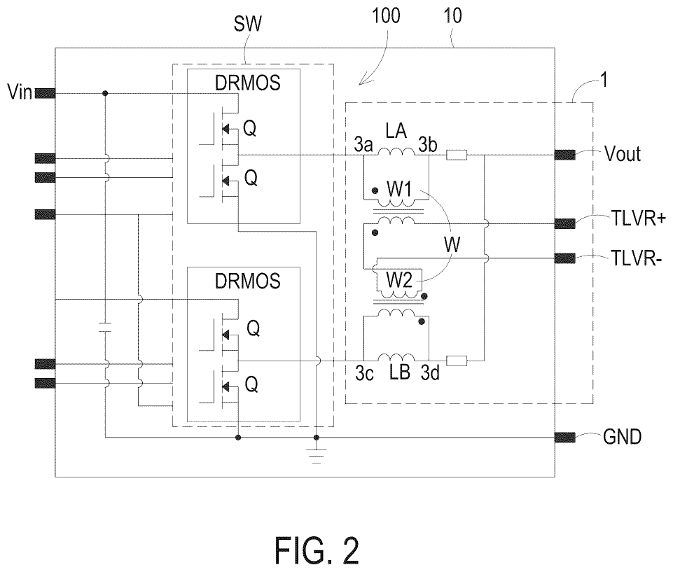

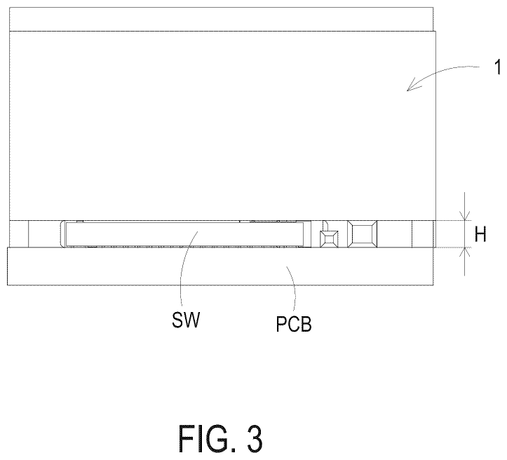

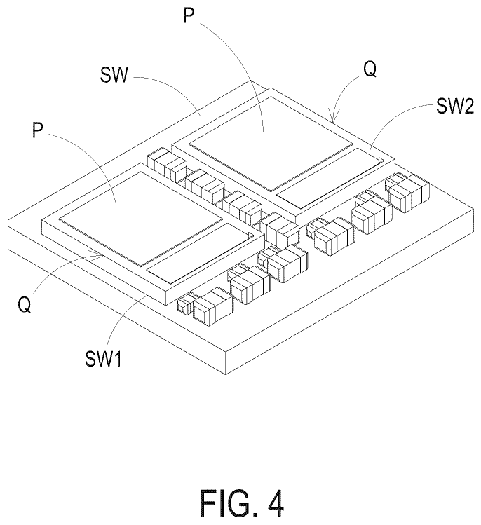

Please refer to FIGS. 1A, 1B, 1C, 2, 3 and 4. FIG. 1A is a schematic perspective view illustrating the structure of a coupling inductor according to an embodiment of the present disclosure and taken from a top viewpoint. FIG. 1B is a schematic exploded view illustrating the structure of the coupling inductor shown in FIG. 1A. FIG. 1C is a schematic perspective view illustrating the structure of the coupling inductor shown in FIG. 1A and taken from a bottom viewpoint. FIG. 2 is a schematic circuit diagram illustrating the circuitry topology of a single-module power conversion circuit where the coupling inductor of FIG. 1A is applied. FIG. 3 schematically illustrates the relationship between the coupling inductor shown in FIG. 1A, a circuit board and a switching device. FIG. 4 is a schematic perspective view illustrating the structure of a switching device and a circuit board shown in FIG. 2.

In this embodiment, a coupling inductor 1 is applied to a single-module power conversion circuit 10. The input terminal of the single-module power conversion circuit 10 may be connected to the input terminals of other single-module power conversion circuits 10 in parallel. The plurality of single-module power conversion circuits 10 in parallel connection are collaboratively formed as a power conversion system. In some embodiments, the number of the single-module power conversion circuits 10 in the power conversion system is even.

The single-module power conversion circuit 10 includes a two-phase buck circuit 100. In the embodiment of FIG. 2, the two-phase buck circuit 100 has a trans-inductor voltage regulator circuitry topology. It is noted that the circuitry topology of the two-phase buck circuit 100 is not restricted. For example, in another embodiment, the two-phase buck circuit 100 has a voltage regulator circuitry topology without any auxiliary winding W.

Please refer to FIG. 2 again. The two-phase buck circuit 100 includes a switching device SW and a coupling inductor 1.

The switching device SW is a heating element. The switching device SW includes at least one switch Q. For example, the switch Q is a Metal-Oxide-Semiconductor Field-Effect Transistor (MOSFET) switch. In some embodiments, the switching device SW is soldered on a circuit board PCB. In an embodiment, the switching device SW includes two DRMOS devices. Each of the DRMOS devices integrates a driver and at least one MOSFET switch into a single package. For example, as shown in FIG. 2, the DRMOS device in the switching device SW includes a driver and two MOSFET switches. That is, each DRMOS device corresponds to two switches Q and a driver (not shown).

The coupling inductor 1 is electrically connected to the switching device SW. As shown in FIG. 1B and FIG. 2, the coupling inductor 1 includes a magnetic core 2 and a winding assembly. The winding assembly is electrically connected to the switching device SW. In an embodiment, the winding assembly includes a first power winding LA, a second power winding LB and at least one auxiliary winding W. The first power winding LA and the second power winding LB are electrically connected to the switching devices SW. In addition, a shared magnetic flux path is provided between the first power winding LA and the second power winding LB. The at least one auxiliary winding W is magnetically coupled with the first power winding LA and the second power winding LB.

In this embodiment, the magnetic core 2 includes top surface 20 and bottom surface 21. The top surface 20 and the bottom surface 21 are opposed to each other. In addition, a portion of the first power winding LA and a portion of the second power winding LB are disposed within the magnetic core 2. The two opposite terminals of the first power winding LA are exposed on the bottom surface 21 of the magnetic core 2 and respectively formed as a first outer connection part 3a and a second outer connection part 3b. Moreover, a portion of the first power winding LA is exposed on the top surface 20 of the magnetic core 2 and configured as a first heat dissipation part 4a. Similarly, the two opposite terminals of the second power winding LB are exposed on the bottom surface 21 of the magnetic core 2 and formed as a third outer connection part 3c and a fourth outer connection part 3d. Moreover, a portion of the second power winding LB is exposed on the top surface 20 of the magnetic core 2 and configured as a second heat dissipation part 4b.

As shown in FIG. 2, the first outer connection part 3a is the left terminal of the first power winding LA, and the first outer connection part 3a is electrically connected to the switching device SW. Similarly, the third outer connection part 3c is the left terminal of the second power winding LB, and the third outer connection part 3c is electrically connected to the switching device SW. When the switching device SW is operated, the generated heat is transferred to the first heat dissipation part 4a and the second heat dissipation part 4b through the first outer connection part 3a and the third outer connection part 3c. In other words, the generated heat is conducted via the first outer connection part 3a and the third outer connection part 3c to the first heat dissipation part 4a and the second heat dissipation part 4b. Consequently, the generated heat is effectively dissipated away.

As shown in FIG. 2, the second outer connection part 3b is the right terminal of the first power winding LA, and the fourth outer connection part 3d is the right terminal of the second power winding LB. The second outer connection part 3b and the fourth outer connection part 3d are electrically connected to each other. In addition, the second outer connection part 3b and the fourth outer connection part 3d are electrically connected to an output terminal Vout of the single-module power conversion circuit 10 to output power.

As mentioned above, one of the two terminals of the first power winding LA and one of the two terminals of the second power winding LB (i.e., the first outer connection part 3a and the third outer connection part 3c) are electrically connected to the switching device SW. In addition, the first power winding LA is exposed on the top surface 20 of the magnetic core 2 and configured as the first heat dissipation part 4a, and the second power winding LB is exposed on the top surface 20 of the magnetic core 2 and configured as the second heat dissipation part 4b. Consequently, the first power winding LA and the second power winding LB are directly connected to the switching device SW to dissipate the heat generated by the switching device SW. Since the thermal resistance is significantly reduced, the heat dissipation performance and the power density of the coupling inductor 1 will be effectively enhanced.

Please refer to FIG. 4. The switching device SW includes two power terminals P. In addition, the switching device SW includes a first outer surface SW1 and a second outer surface SW2. The power terminals P are exposed on the second outer surface SW2 of the switching device SW. Furthermore, the two power terminals Pare electrically connected to the first outer connection part 3a and the third outer connection part 3c, respectively. In an embodiment, the first power winding LA and the second power winding LB are conductive metal pieces. In addition, the first power winding LA and the second power winding LB can be bent at least once according to the practical requirements. In some embodiments, each of the first power winding LA, the second power winding LB and the at least one auxiliary winding W has one turn.

In some embodiments, the first heat dissipation part 4a and the second heat dissipation part 4b have planar structures, and the first heat dissipation part 4a and the second heat dissipation part 4b are disposed on the top surface 20 of the magnetic core 2. In addition, the first heat dissipation part 4a and the second heat dissipation part 4b are coplanar with each other. Moreover, a portion of the first power winding LA is configured as the first heat dissipation part 4a, and a portion of the second power winding LB is configured as the second heat dissipation part 4b. The projected area of the first heat dissipation part 4a on the horizontal plane is larger than the projected area of the other portion of the first power winding LA on the horizontal plane. Similarly, the projected area of the second heat dissipation part 4b on the horizontal plane is larger than the projected area of the other portion of the second power winding LB on the horizontal plane. For example, the horizontal plane is a plane parallel to the top surface 20 of the magnetic core 2. Since the areas of the first heat dissipation part 4a and the second heat dissipation part 4b are relatively larger, the heat dissipation efficacy of the first power winding LA and the second power winding LB will be increased.

In order to improve the heat dissipation efficacy of the first heat dissipation part 4a and the second heat dissipation part 4b, the coupling inductor 1 further includes a heat dissipation mechanism (not shown). A surface of the heat dissipation mechanism is disposed on the first heat dissipation part 4a and the second heat dissipation part 4b. For example, the heat dissipation mechanism includes heat dissipation fins, cold plates or any other heat dissipation structures. In the embodiment shown in FIGS. 1A and 1B, the heat dissipation mechanism includes a first heat dissipation plate H1 and a second heat dissipation plate H2. The first heat dissipation part 4a and the second heat dissipation part 4b are respectively disposed on the first heat dissipation plate H1 and the second heat dissipation plate H2.

In an embodiment, a portion of the at least one auxiliary winding W is partially disposed within the magnetic core 2. In addition, the two opposite terminals of the at least one auxiliary winding W are exposed on the bottom surface 21 of the magnetic core 2 and respectively formed as a fifth outer connection part 3e and a sixth outer connection part 3f. As shown in FIG. 2, the fifth outer connection part 3e is configured as a positive output terminal TLVR+ of the at least one auxiliary winding W, and the sixth outer connection part 3f is configured as a negative output terminal TLVR− of the at least one auxiliary winding W.

In an embodiment, the coupling inductor 1 shown in FIG. 2 is a positive coupling inductor. That is, the winding direction of the first power winding LA and the winding direction of the second power winding LB are identical. Consequently, the first power winding LA and the second power winding LB are positively coupled with each other.

Please refer to FIG. 1B again. In an embodiment, the at least one auxiliary winding W includes a first auxiliary winding W1 and a second auxiliary winding W2. The first auxiliary winding W1 is coupled with the first power wining LA. The second auxiliary winding W2 is coupled with the second power winding LB. In addition, the first auxiliary winding W1 and the second auxiliary winding W2 are electrically connected to each other.

Please refer to FIG. 1A again. As mentioned above, the coupling inductor 1 includes the first heat dissipation plate H1 and the second heat dissipation plate H2. The first heat dissipation plate H1 is disposed on the first heat dissipation part 4a, and the second heat dissipation plate H2 is disposed on the second heat dissipation part 4b. Moreover, the magnetic core 2 is symmetrically divided into an upper half region and a lower half region with respect to a horizontal plane PS. The volume of the section of the first power winding LA disposed in the upper half region of the magnetic core 2 is larger than the volume of the section of the first power winding LA disposed in the lower half region of the magnetic core 2. Similarly, the volume of the section of the second power winding LB disposed in the upper half region of the magnetic core 2 is larger than the volume of the section of the second power winding LB disposed in the lower half region of the magnetic core 2.

In an embodiment, the first power winding LA and the second power winding LB are structurally symmetrical to each other, and the winding methods are identical. If the current direction of the first power winding LA and the current direction of the second power winding LB are identical, the magnetic fields of them are mutually strengthened. Under this circumstance, a positive coupling relationship between the first power winding LA and the second power winding LB is established. After the first power winding LA, the second power winding LB and the at least one auxiliary winding W are produced, the magnetic core 2 is formed by compression molding using ferrite or powder core material. Due to integration and compression, the at least one auxiliary winding W has only two external pins (i.e., the positive output terminal TLVR+ and the negative output terminal TLVR−). Since the pin number is reduced, the occupied area of the pins is reduced. Moreover, since the first auxiliary winding W1 and the second auxiliary wining W2 are electrically connected to each other in series and the magnetic core 2 is implemented with an integrated structure, the leakage inductance is minimized, and the higher power density is achievable.

In some embodiments, the first outer connection part 3a, the third outer connection part 3c and the bottom surface 21 of the magnetic core 2 are coplanar with each other. Consequently, through the first outer connection part 3a and the third outer connection part 3c, the coupling inductor 1 can be directly soldered on the solder pad on the surface of the switching device SW, or the coupling inductor 1 can be directly soldered on the circuit board PCB. In addition, the second outer connection part 3b, the fourth outer connection part 3d, the fifth outer connection part 3e and the sixth outer connection part 3f are coplanar with each other. In some embodiments, there is a height difference H between each of the second outer connection part 3b, the fourth outer connection part 3d, the fifth outer connection part 3e and the sixth outer connection part 3f and the bottom surface 21 of the magnetic core 2. Due to the height difference H, these outer connection parts can be securely soldered on the circuit board PCB under the bottom surface 21 of the magnetic core 2. Consequently, the soldering stability will be increased. It is noted that the height difference can be designed according to the practical requirements.

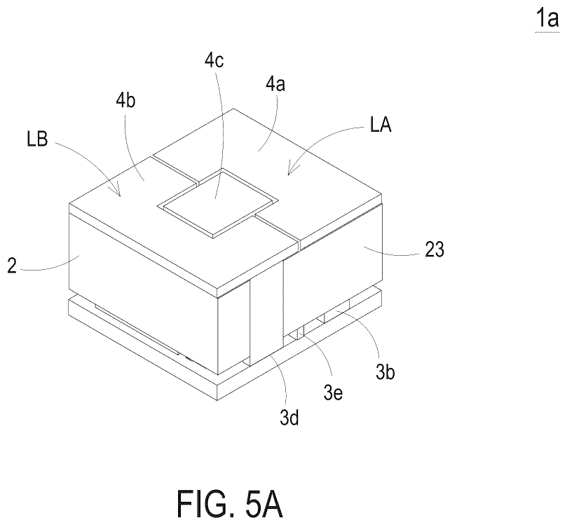

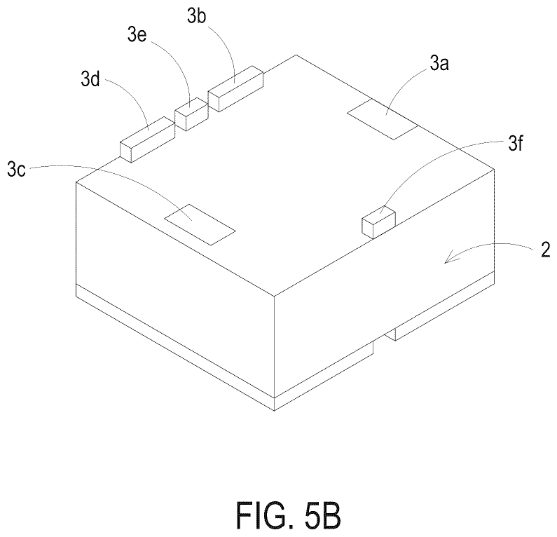

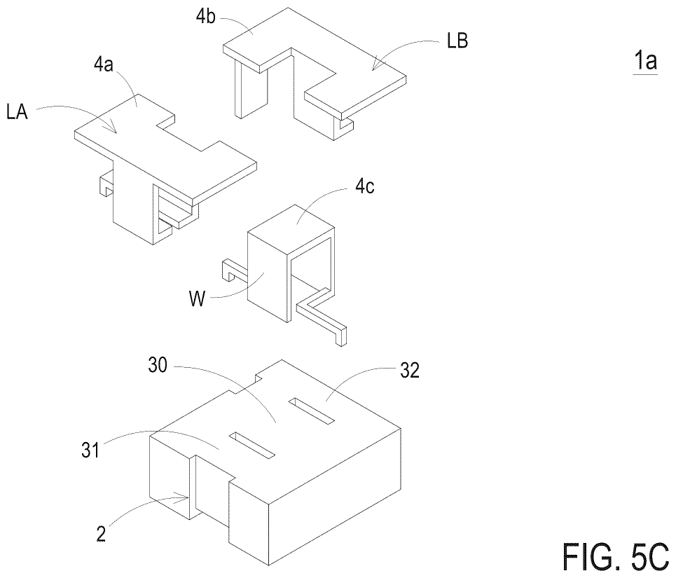

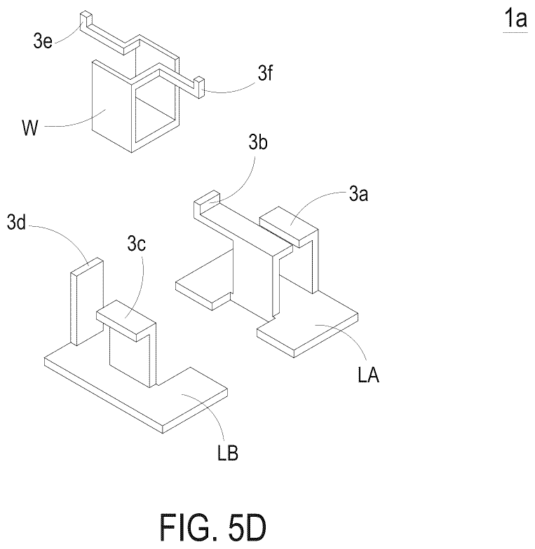

Please refer to FIGS. 5A, 5B, 5C and 5D as well as FIG. 2. FIG. 5A is a schematic perspective view illustrating the structure of a power conversion module including a coupling inductor according to an embodiment of the present disclosure and taken from a top viewpoint. FIG. 5B is a schematic perspective view illustrating the structure of the coupling inductor shown in FIG. 5A and taken from a bottom viewpoint. FIG. 5C is a schematic exploded view illustrating the coupling inductor shown in FIG. 5A. FIG. 5D schematically illustrates a winding assembly of the coupling inductor shown in FIG. 5A.

Similarly, the coupling inductor 1a of this embodiment can be applied to the single-module power conversion circuit 10 shown in FIG. 2. Since the structure and the function of the coupling inductor 1a are similar to those of the coupling inductor 1, detailed descriptions thereof will be omitted. As mentioned above, the coupling inductor 1 in the embodiment shown in FIGS. 1A-1C is a positive coupling inductor. In contrast, the coupling inductor 1a in this embodiment is a negative coupling inductor. That is, the winding direction of the first power winding LA and the winding direction of the second power winding LB are opposite. Since the winding directions are opposite, if the current directions are opposite, the magnetic fields generated by the first power winding LA and the second power winding LB will mutually weaken each other. Consequently, the first power winding LA and the second power winding LB are collaboratively formed as a negatively coupled structure. Due to the negatively coupled structure, the AC magnetic flux loss of the magnetic core 2 is reduced. Consequently, the efficiency and the thermal performance of the single-module power conversion circuit 10 will be improved.

In this embodiment, the magnetic core 2 includes a middle leg 30 and two lateral legs 31 and 32. The at least one auxiliary winding W is wound around the middle leg 30. The first power winding LA is wound around the lateral leg 31. The second power winding LB is wound around the lateral leg 32.

In an embodiment, a portion of the at least one auxiliary winding W is exposed on the top surface 20 of the magnetic core 2 and formed as a planar section 4c. The planar section 4c is coplanar on a plane parallel to the top surface of the magnetic core with the first heat dissipation part 4a and the second heat dissipation part 4b. In addition, the planar section 4c is substantially located at a center region of the top surface 20 of the magnetic core 2 and is surrounded by the first heat dissipation part 4a and the second heat dissipation part 4b.

Please refer to FIG. 5A. A portion of the first power winding LA is exposed outside a lateral wall 23 of the magnetic core 2 and connected to the first heat dissipation part 4a and the first outer connection part 3a. Similarly, a portion of the second power winding LB is exposed outside the lateral wall 23 of the magnetic core 2 and connected to the second heat dissipation part 4b and the third outer connection part 3c.

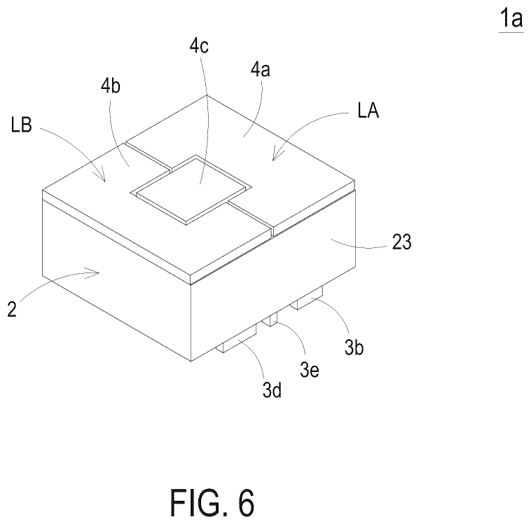

Please refer to FIG. 6. FIG. 6 is a schematic perspective view illustrating a variant example of the coupling inductor shown in FIG. 5A. In this embodiment, the first power winding LA and/or the second power winding LB are disposed within the magnetic core 2 and are partially exposed on the top surface 20 and the bottom surface 21 of the magnetic core 2. However, the first power winding LA and/or the second power winding LB are not exposed on the lateral wall 23 of the magnetic core 2.

Please refer to FIGS. 5C and 5D. In an embodiment, the auxiliary winding W is a single winding. The auxiliary winding Wis coupled with the first power winding LA and the second power winding LB.

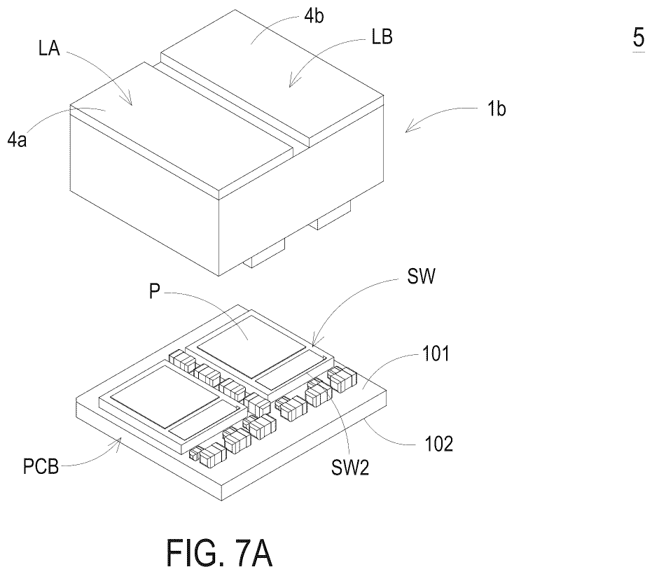

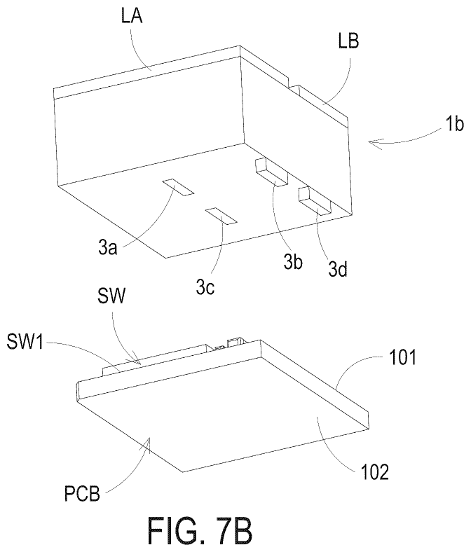

Please refer to FIGS. 7A and 7B. FIG. 7A is a schematic exploded view illustrating the structure of a power conversion module according to an embodiment of the present disclosure. FIG. 7B is a schematic exploded view illustrating the power conversion module shown in FIG. 7A and taken from another viewpoint. Similarly, the power conversion module 5 of this embodiment can be applied to the single-module power conversion 10 shown in FIG. 2. Since some components of the power conversion module 5 are similar to those shown in FIGS. 5A to 5D and FIG. 2, the detailed descriptions thereof will be omitted. In this embodiment, the power conversion module 5 includes a circuit board PCB and a coupling inductor 1b. The circuit board PCB includes a first surface 101 and a second surface 102. Furthermore, a switching device SW serving as the heating element is disposed on the circuit board PCB. The first surface 101 and the second surface 102 are opposed to each other. The switching device SW includes a first outer surface SW1 and the second outer surface SW2, which are opposed to each other. The first outer surface SW1 of the switching device SW is disposed on the first surface 101 of the circuit board PCB.

The structure of the coupling inductor 1b is similar to the structure of the coupling inductor 1 shown in FIG. 1A. However, the coupling inductor 1b in this embodiment has a voltage regulator circuitry topology, rather than the trans-inductor voltage regulator circuitry topology. In this embodiment, the coupling inductor 1b is not equipped with the auxiliary winding W shown in FIG. 1B. The coupling inductor 1b is connected with the second outer surface SW2 of the switching device SW. In addition, the second outer connection part 3b of the first power winding LA and the fourth outer connection part 3d of the second power winding LB are soldered on the first surface 101 of the circuit board PCB. Furthermore, a single channel is formed in the region between the first heat dissipation part 4a of the first power winding LA and the second heat dissipation part 4b of the second power winding LB, and the first heat dissipation part 4a and the second heat dissipation part 4b are arranged on the top surface 20 of the magnetic core 2. In other words, the functions of the first heat dissipation part 4a and the second heat dissipation part 4b are similar to those of the first heat dissipation plate H1 and the second heat dissipation plate H2 shown in FIG. 1A.

As mentioned above, the switching device SW of the present disclosure includes two DRMOS devices. Each of the DRMOS devices integrates a driver and at least one MOSFET switch into a single package. For example, as shown in FIG. 2, the DRMOS device in the switching device SW includes a driver and two MOSFET switches. That is, each DRMOS device corresponds to two switches Q and a driver.

Especially, the MOSFET switch used in the switching device SW of the present disclosure, which is different from the conventional MOSFET switch, has a window on the top surface. The conventional MOSFET switch usually has no window on its top surface. Even if the window is formed on the top surface, the power terminal of the conventional MOSFET switch is not exposed. In accordance with the present disclosure, the power terminal P of the switching device SW is exposed outside the second outer surface SW2. In this way, the heat conduction efficiency is increased, the thermal resistance is reduced, and the electrical connection is achievable. Since the window is formed on the second outer surface SW2 of the switching device SW, it is more convenient for the first power winding LA and the second power winding LB of the coupling inductor 1b to be directly connected to the switching device SW. The larger window area on the first outer surface SW2 of the switching device SW is beneficial for the heat conduction of the coupling inductor 1b. Due to the attachment between the coupling inductor 1b and the switching device SW, the thermal resistance between the first winding LA and the switching device SW and the thermal resistance between the second winding LB and the switching device SW will be largely reduced. Consequently, the efficiency of the heat conduction is enhanced. In other words, the heat generated by the first power winding LA and the second power winding LB can be transferred to the switching device SW and the heat dissipation mechanism. Due to this exposed design, the top surface of the coupling inductor 1b (i.e., the first heat dissipation part 4a and the second heat dissipation part 4b) can be exposed to the ambient air. Since the heat dissipation area is increased, the efficacy of the heat dissipation through radiation and convection will be enhanced, and the overall thermal performance will be increased.

Especially, the coupling inductor 1b can be implemented by using a single circuit board PCB. The vertical power supply structure not only ensures the power transmission efficiency, but also simplifies the overall design. In practical manufacturing and application, only one magnetic core 2 needs to be processed, and thus the complexity and the production cost are reduced. In the above embodiment, the first power winding LA and the second power winding LB are disposed on and exposed outside the top surface 20 of the magnetic core 2. This attachment design is not only applied to the voltage regulator circuitry topology and the trans-inductor voltage regulator circuitry topology. That is, this attachment design is applied to any other appropriate type of inductor.

From above descriptions, the present disclosure provides a coupling inductor and a power conversion module with the coupling inductor. A terminal of each of the first power winding and the second power winding of the coupling inductor is electrically connected to the switching device. In addition, the first power winding and the second power winding of the coupling inductor are exposed on the top surface of the magnetic core and respectively configured as the first heat dissipation part and the second heat dissipation part. Consequently, the first power winding and the second power winding are in direct contact with the switching device. Since the thermal resistance is greatly reduced, the heat dissipation performance and the power density of the coupling inductor and the power conversion module with the coupling inductor can be effectively enhanced.

It is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A coupling inductor electrically connected to a heating element, the coupling inductor comprising:
a magnetic core having a top surface and a bottom surface opposite to each other; and
a winding assembly comprising a first power winding and a second power winding,
wherein a shared flux path is provided between the first power winding and the second power winding,
wherein the first power winding and the second power winding are partially disposed within the magnetic core,
wherein two opposite terminals of the first power winding are exposed on the bottom surface of the magnetic core and respectively formed as a first outer connection part and a second outer connection part, and a portion of the first power winding is exposed on the top surface of the magnetic core and configured as a first heat dissipation part,
wherein two opposite terminals of the second power winding are exposed on the bottom surface of the magnetic core and respectively formed as a third outer connection part and a fourth outer connection part, and a portion of the second power winding is exposed on the top surface of the magnetic core and configured as a second heat dissipation part,
wherein the first outer connection part and the third outer connection part are electrically connected to the heating element, and heat generated by the heating element is conducted via the first outer connection part and the third outer connection part to the first heat dissipation part and the second heat dissipation part, and the winding assembly outputs power via the second outer connection part and the fourth outer connection part.

2. The coupling inductor according to claim 1, wherein the heating element is a switching device comprising a power terminal, the power terminal is exposed on an outer surface of the switching device, and the power terminal is electrically connected to the first outer connection part and the third outer connection part.

3. The coupling inductor according to claim 1, wherein the first power winding and the second power winding are conductive metal pieces.

4. The coupling inductor according to claim 3, wherein the first heat dissipation part and the second heat dissipation part have planar structures, and the first heat dissipation part and the second heat dissipation part are disposed on the top surface of the magnetic core, wherein the first heat dissipation part and the second heat dissipation part are coplanar with each other.

5. The coupling inductor according to claim 4, wherein:
a projected area of the first heat dissipation part on a plane parallel to the top surface of the magnetic core is larger than a projected area of the other portion of the first power winding on the same plane; and
a projected area of the second heat dissipation part on the plane parallel to the top surface of the magnetic core is larger than a projected area of the other portion of the second power winding on the same plane.

6. The coupling inductor according to claim 4, wherein the coupling inductor further comprises a heat dissipation mechanism, and a surface of the heat dissipation mechanism is disposed on the first heat dissipation part and the second heat dissipation part.

7. The coupling inductor according to claim 1, wherein the coupling inductor further comprises at least one auxiliary winding partially disposed within the magnetic core, and the at least one auxiliary winding is coupled with the first power winding and the second power winding, wherein two opposite terminals of the at least one auxiliary winding are exposed on the bottom surface and respectively formed as a fifth outer connection part and a sixth outer connection part.

8. The coupling inductor according to claim 7, wherein a winding direction of the first power winding and a winding direction of the second power winding are identical, so that the first power winding and the second power winding are positively coupled with each other.

9. The coupling inductor according to claim 8, wherein a portion of the at least one auxiliary winding is exposed on the top surface of the magnetic core and formed as a planar section, wherein the planar section, the first heat dissipation part and the second heat dissipation part are coplanar on a plane parallel to the top surface of the magnetic core.

10. The coupling inductor according to claim 8, wherein the at least one auxiliary winding comprises a first auxiliary winding and a second auxiliary winding, wherein the first auxiliary winding is coupled with the first power winding, the second auxiliary winding is coupled with the second power winding, and the first auxiliary winding and the second auxiliary winding are electrically connected to each other.

11. The coupling inductor according to claim 7, wherein a winding direction of the first power winding and a winding direction of the second power winding are opposite, so that the first power winding and the second power winding are negatively coupled with each other.

12. The coupling inductor according to claim 11, wherein the magnetic core comprises a middle leg, a first lateral leg and a second lateral leg, wherein the at least one auxiliary winding is wound around the middle leg, the first power winding is wound around the first lateral leg, and the second power winding is wound around the second lateral leg.

13. The coupling inductor according to claim 11, wherein a portion of the at least one auxiliary winding is exposed on the top surface and formed as a planar section, wherein the planar section, the first heat dissipation part and the second heat dissipation part are coplanar on a plane parallel to the top surface of the magnetic core.

14. The coupling inductor according to claim 1, wherein the coupling inductor further comprises a first heat dissipation plate and a second heat dissipation plate, wherein the first heat dissipation plate is disposed on the first heat dissipation part, and the second heat dissipation plate is disposed on the second heat dissipation part.

15. The coupling inductor according to claim 1, wherein the magnetic core is divided into an upper half region and a lower half region with respect to a horizontal plane, and a volume of a section of the first power winding disposed in the upper half region is larger than a volume of a section of the first power winding in the lower half region.

16. A power conversion module, comprising:
a circuit board having a first surface and a second surface opposite to each other, and a heating element is disposed on the first surface of the circuit board, wherein the heating element has a first outer surface and a second outer surface opposite to each other; and
a coupling inductor electrically connected to the second outer surface of the heating element, wherein the coupling inductor comprises:
a magnetic core having a top surface and a bottom surface opposite to each other; and
a winding assembly comprising a first power winding and a second power winding,
wherein a shared flux path is provided between the first power winding and the second power winding,
wherein the first power winding and the second power winding are partially disposed within the magnetic core,
wherein two opposite terminals of the first power winding are exposed on the bottom surface of the magnetic core and respectively formed as a first outer connection part and a second outer connection part, and a portion of the first power winding is exposed on the top surface of the magnetic core and configured as a first heat dissipation part,
wherein two opposite terminals of the second power winding are exposed on the bottom surface of the magnetic core and respectively formed as a third outer connection part and a fourth outer connection part, and a portion of the second power winding is exposed on the top surface of the magnetic core and configured as a second heat dissipation part,
wherein the first outer connection part and the third outer connection part are electrically connected to the heating element, and heat generated by the heating element is conducted via the first outer connection part and the third outer connection part to the first heat dissipation part and the second heat dissipation part, the winding assembly outputs power via the second outer connection part and the fourth outer connection part, and the second outer connection part and the fourth outer connection part are soldered on the first surface.

17. The power conversion module according to claim 16, wherein the heating element is a switching device comprising a power terminal, the power terminal is exposed on the second outer surface of the switching device, and the power terminal is electrically connected to the first outer connection part and the third outer connection part.
